(19) United States
(12) Patent Application Publication
(10) Pub. No.: US 2010/0291772 A1
(43) Pub. Date: Nov. 18, 2010

(54) Semiconductor Manufacturing Method

(76) Inventors: Cheng-Chung YANG, Huatan Township (TW); Ming-Sen Hsu, Sinhua Township (TW)

Correspondence Address: SINORICA, LLC, 2275 Research Blvd., Suite 500, ROCKVILLE, MD, 20850, US

(21) Appl. No.: 12/466,468

(22) Filed: May 15, 2009

(51) Int. Cl. H01L 21/30

(52) U.S. Cl. 438/796; 257/E21.211

(57) ABSTRACT

The present invention discloses a semiconductor manufacturing method. The method for activating a p-type impurity doped in a semiconductor element in a chamber comprises that a vacuum pressure is exerted to the chamber first, and the semiconductor element is heated to a preset temperature and the heating is persisted for a preset period to activate the p-type impurity doped in the semiconductor element.

### FIELD OF THE INVENTION

The invention relates to a semiconductor manufacturing method, in particular to a method for activating the p type impurity doped in a semiconductor element.

### BACKGROUND OF THE INVENTION

At present, the gallium nitride compound (GaₓAl₁₋ₓN and GaₓIn₁₋ₓN, 0≦x≦1) among semiconductor materials is widely applied due to its good luminescence characteristic under the room temperature. A p-type impurity doped with the nitride compound must be activated by an activation process for producing a large number of p-type carriers and reducing the resistance of a semiconductor. Currently, a more common p-type impurity of impurities is magnesium (Mg). The internal nitrogen element of the semiconductor is provided by the ammonia (NH3) and the hydrogen element released by ammonia (NH3) forms a Mg—H bond with the p-type impurity (magnesium). The method of activating the p-type impurity is to provide energy to the Mg—H bond for breaking the Mg—H bond, but after breaking the Mg—H bond, the hydrogen atom still remains within gallium nitride or is adsorbed by the defect inside gallium nitride. When the temperature of a chamber returns to room temperature, the hydrogen atom can bind to magnesium again and we must provide greater energy for removing the hydrogen atoms from gallium nitride (GaN).

In a conventional method of manufacturing a gallium nitride compound semiconductor, which is disclosed by U.S. Pat. No. 5,306,662, the temperature of a chamber is raised to exceed 400° C. (600° C.˜1200° C.) for annealing to achieve the effect of activating the p-type impurity. In an embodiment disclosed in the U.S. Pat. No. 5,306,662, the temperature of a chamber is raised to 1030° C. for proceeding the epitaxy of the gallium nitride compound and the p-type impurity is actived by introducing hydrogen gas. At this temperature, an epitaxy process is proceeded for doping the magnesium into the semiconductor. After the epitaxy process is finished, the chamber temperature is cooled to a specific temperature, and the semiconductor is taken out from the chamber and then transferred to an annealing process. During the annealing process, the semiconductor are heated to 800° C. and then annealed at 800° C. for 20 minutes under a atmosphere filled with nitrogen gas. The conventional method is performed with an inextricable process of repeatedly raising temperature and lowering temperature for several times in the chamber, and its disadvantages are time-consuming, miscellaneous procedure and high cost. In addition, the activation method remains a lot of residual hydrogen and is disadvantageous to the relevant follow-up process.

Another conventional method of manufacturing a gallium nitrogen compound semiconductor is disclosed by TW Patent No. 516101. In this convention method, the temperature of a chamber is raised to 1000° C. and the p-type impurity is actived by introducing hydrogen gas. While the chamber is cooled down to 700° C. slowly, the rate of the hydrogen gas and the ammonia gas flowed into the chamber is also reduced slowly till ceasing flow of these gas, and the rate of the nitrogen gas flowed into the chamber is increased to 20 1/min at the same time. This conventional method can reduce complexity of process but it still needs the cooling procedure before further process. The activation method remains a lot of residual hydrogen and is disadvantageous to the relevant follow-up process.

In view of the foregoing shortcomings of the prior art, the inventor of the present invention based on years of experience in the related industry to conduct extensive researches and experiments, and finally developed a semiconductor manufacturing method to overcome the existing problems.

### SUMMARY OF THE INVENTION

A primary objective of the present invention is to provide a semiconductor manufacturing method to solve the above-mentioned problems. The method is applied to activate the p type impurity doped in a semiconductor element, and is performed in a chamber. The method comprises the steps of:

i) exerting a vacuum pressure to the chamber;

ii) heating the semiconductor element to a preset temperature; and

iii) heating the chamber continuously for a preset period to activate the p type impurity doped in the semiconductor element.

In this environment with the vacuum pressure, the p-type impurity doped in the semiconductor element can be activated without heating and cooling repeatedly. Furthermore, in this vacuum pressure, the p-type impurity can be activated with the preset temperature less than 400° C. After heating to activate the p-type impurity for the preset time, a transparent conductive layer can be formed on the semiconductor element directly. By the way, the method can omit the cooling step for simplifying the process, saving time and reducing the cost and the method can reduce the residual amount of hydrogen for simplifying the follow-up process.

To make it easier for our examiners to understand the technical characteristics and functions of the present invention, preferred embodiments are used for the detailed description of the invention as follows.

### BRIEF DESCRIPTION OF THE DRAWINGS

The accompanying drawings, which are incorporated in and from a part of this specification, illustrate embodiments of the invention and, together with the description, serve to explain the principles of the invention.

None.

### DETAILED DESCRIPTION OF PREFERRED EMBODIMENTS

Exemplary embodiments of the present invention are described herein in the context of a semiconductor manufacturing method. The same reference indicators will be used throughout the following detailed description to refer to the same or like parts.

During an epitaxy process, a semiconductor material is usually doped into a wafer. Preferably, the semiconductor material for doping is a p type impurity. Preferably, the semiconductor element of the wafer is selected from the group consisting of the III-V group and the II-VI group semiconductor element, such as gallium nitrogen compound (GaₓAl₁₋ₓN and GaₓIn₁₋ₓN, 0 x 1), which can be applied for a light emitting diode (LED). Preferably, the p-type impurity is able to be magnesium (Mg), zinc (Zn), carbon (C) and beryllium (Be), or other p-type metal.

An embodiment of the method comprises the following steps. First, the semiconductor element is put into a chamber, and then a vacuum pressure is imposed to the chamber, and the vacuum pressure is less than 10⁻² torr. And then, the chamber is heated to a preset temperature with lower than 400° C. Then, the chamber is continuously heated for a preset period to activate the p type impurity doped in the semiconductor element. Preferably, the preset period is longer than 1 min. After the preset period, the p-type impurity doped in the semiconductor element has been activated, and finally, a transparent conductive layer is formed on the semiconductor element. Preferably, the transparent conductive layer is able to be indium tin oxide (ITO), cadmium tin oxide (CTO), indium tin oxide (ITO), cadmium tin oxide (CTO), tin-doped silver indium oxide (AgInO2:Sn), aluminum-doped zinc oxide (ZnO:Al; AZO) or aluminum zinc oxide (AZO). During the abovementioned process, the temperature of the chamber is kept lower than 400° C., and the temperature required for forming a transparent conductive layer is about 250° C. to 400° C., so the transparent conductive layer can be directly formed on the semiconductor element after activating the p type impurity doped in the semiconductor element without necessarily recooling. Furthermore, in the vacuum pressure of the environment, it is not necessary for the complicated steps of repeated heating and cooling, and the purpose for activating the p-type impurity in the semiconductor element is completed below 400° C. Therefore, the method of the present invention not only achieves the effect of activating the p-type impurity, but also simplifies the semiconductor manufacturing process by omitting the cooling steps to save time and reduce the cost. In addition, the method can reduce the residual amount of hydrogen for simplifying the follow-up process.

It should be noted that the ammonia gas, the hydrogen gas, the TMG gas and the Cp₂Mg gas are inputted into the chamber for respectively serving as the sources of nitrogen, hydrogen, gallium and magnesium, and such technique are well-known. For the sake of brevity, further discussion is omitted

TABLE 1
300 μm × 300 μm LED Chip

| | | Vacuum | Vacuum | Vacuum |
|---|---|---|---|---|
| Optoelectronic | | activation | activation | activation |
| property | Unactivated | at 200° C. | at 300° C. | at 350° C. |
| Vf at 20 mA | 3.8 V | 3.78 V | 3.3 V | 3.3 V |
| ESD (HBM) | 100 V | 100 V | 2 KV | 2 KV |

Table 1 shows a comparative statement of driving voltage (Vf) and electrostatic discharge (ESD) at different temperatures. An unactivated LED chip size is 300 μm×300 μm. The unactivated LED chip Vf is 3.8 V and ESD voltage is 100 V. After being activated at 200° C. and under vacuum, an activated LED chip has Vf of 3.78 V and ESD of 100 V. After being activated at 300° C. and under vacuum, the activated LED chip has Vf of 3.3V and ESD of 2 KV. After being activated at 350° C. and under vacuum, the activated LED chip has Vf of 3.3 V and ESD of 2 KV.

In accordance with the table 1, the activated LED chip which is activated at 200° C. and under vacuum has similar property with the unactivated LED chip, but the Vf of the activated LED chip which is at 300° C. and under vacuum decreases to 3.3V, and ESD of this activated LED chip increases to 2 KV. Therefore the vacuum activation process is an effective process. In accordance with data of the table 1, the vacuum activation process is preferred to perform at the temperature exceeding 300° C. for better efficiency.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A semiconductor manufacturing method, applicable in a chamber to activate a p-type impurity doped in a semiconductor element, comprising steps of:
exerting a vacuum pressure to the chamber;
heating the semiconductor element to a preset temperature; and
heating continuously for a preset period.

2. The semiconductor manufacturing method in claim 1, wherein a transparent conductive layer is further formed on the semiconductor element.

3. The semiconductor manufacturing method in claim 2, wherein the transparent conductive layer is made of a material selected from a group consisting of indium tin oxide (ITO), cadmium tin oxide (CTO), tin-doped silver indium oxide (AgInO2:Sn), aluminum-doped zinc oxide (ZnO:Al; AZO) and aluminum zinc oxide (AZO).

4. The semiconductor manufacturing method in claim 1, wherein the semiconductor element is selected from the group consisting of a III-V group semiconductor element and a II-VI group semiconductor element.

5. The semiconductor manufacturing method in claim 1, wherein the p-type impurity is selected from the group consisting of magnesium (Mg), zinc (Zn), carbon (C) and beryllium (Be).

6. The semiconductor manufacturing method in claim 1, wherein the preset temperature is lower than 400° C.

7. The semiconductor manufacturing method in claim 1, wherein the vacuum pressure is lower than 10⁻² torr.

8. The semiconductor manufacturing method in claim 1, wherein the preset period is the time required for activating the p-type impurity doped in the semiconductor element.
